(19) United States
(12) Patent Application Publication
(10) Pub. No.: US 2024/0343554 A1
(43) Pub. Date: Oct. 17, 2024

(54) MICROELECTROMECHANICAL COMPONENT

(71) Applicant: Robert Bosch GmbH, Stuttgart (DE)

(72) Inventors: Jochen Reinmuth, Reutlingen (DE); Christoph Schelling, Stuttgart (DE)

(21) Appl. No.: 18/634,167

(22) Filed: Apr. 12, 2024

(30) Foreign Application Priority Data
Apr. 17, 2023 (DE) 10 2023 203 465.4

(51) Int. Cl. B81B 3/00

(52) U.S. Cl. CPC B81B 3/0021; B81B 2201/0257; B81B 2201/0264; B81B 2203/0127

(57) ABSTRACT

A microelectromechanical component for interacting with a pressure gradient of a fluid. The microelectromechanical component has a substrate with a through-cavity, and a membrane structure which at least partially spans the through-cavity and has a central support structure and two membranes. A second membrane of the membrane structure has a second electrically conductive membrane electrode layer. The central support structure has a center electrode and a contacting element. The membranes are mechanically connected by spacer elements. The membrane structure has an inner region, an outer region, and a fastening region. The inner region is arranged centrally above the through-cavity. The outer region is arranged between the inner region and the fastening region. The fastening region is fastened to the substrate. The center electrode is arranged entirely within the inner region. The contacting element extends from the center electrode via the outer region into the fastening region.

### CROSS REFERENCE

The present application claims the benefit under 35 U.S.C. § 119 of German Patent Application No. DE 10 2023 203 465.4 filed on Apr. 17, 2023, which is expressly incorporated herein by reference in its entirety.

### FIELD

The present invention relates to a microelectromechanical component and to a method for producing a microelectromechanical component.

### BACKGROUND INFORMATION

Microphones which contain a capacitively readable microelectromechanical system (MEMS) are particularly powerful with regard to signal-to-noise ratio, energy consumption, and further processability. This has resulted in electret microphones being largely replaced by MEMS microphones. Such MEMS microphones can have a double membrane, wherein a negative pressure is enclosed between the two membranes, whereby a significant increase in the signal-to-noise ratio is possible. In this concept, the fluidic damping between a rigid back electrode (backplate) and the movable back-pressure membrane is almost completely eliminated. This is achieved by, instead of the back electrode, a center electrode being mounted in a negative-pressure region between two membranes coupled to one another. The membranes are generally connected to one another by support elements in order to be robust in relation to an external pressure. In addition to the use as microphones, such microelectromechanical systems with a double membrane can also be used as a loudspeaker or as a pressure sensor.

MEMS microphones are described in German Patent Application No. DE 10 2014 212 340 A1 and U.S. Patent No. 10,362,408 B1. One problem of these microelectromechanical systems with a double membrane is represented by a low deflection of the membranes in edge regions, which reduces a tappable change in capacitance. German Patent Application No. DE 10 2017 204 023 A1 describes providing the membranes with an insulation element in order that only a central region with a large deflection needs to be taken into account in the determination of the change in capacitance. However, such insulation elements are not simple to implement technically.

### SUMMARY

An object of the present invention is to provide an improved microelectromechanical component. A further object of the present invention is to provide a production method for such a microelectromechanical component. These objects may be achieved features of the present invention. Advantageous developments of the present invention are disclosed herein.

The present invention relates to a microelectromechanical component for interacting with a pressure gradient of a fluid. According to an example embodiment of the present invention, the microelectromechanical component has a substrate with a through-cavity and a membrane structure which at least partially spans the through-cavity. The membrane structure has a central support structure and two membranes. A first membrane of the membrane structure has a first electrically conductive membrane electrode layer. A second membrane of the membrane structure has a second electrically conductive membrane electrode layer. The central support structure has a center electrode and a contacting element. The first membrane and the second membrane are mechanically connected by means of spacer elements. The first membrane and the second membrane are able to deform along a vertical movement direction. The membrane structure has an inner region, an outer region, and a fastening region. The inner region is arranged centrally above the through-cavity. The outer region is arranged between the inner region and the fastening region. The fastening region is fastened to the substrate. The center electrode is arranged entirely within the inner region. The contacting element extends from the center electrode via the outer region into the fastening region. The contacting element occupies less than thirty, preferably less than ten, percent of an area of the outer region.

In particular, the central support structure can be free of electrically conductive material, apart from the contacting element, in the outer region. In that the central support structure has only the contacting element in the outer region and can otherwise be free of electrically conductive material, the evaluation of a change in capacitance is simplified since a change in capacitance of the center electrode essentially has to be evaluated with the membranes displaced in the inner region relative to the center electrode, and a movement of the membranes in the outer region makes only a small contribution to the change in capacitance due to the contacting element. As a result, a sensitivity can be increased overall.

The microelectromechanical component can in particular sense the pressure gradient of the fluid and thus be designed as a microphone or pressure sensor. Furthermore, the microelectromechanical component can generate the pressure gradient and then be designed as a loudspeaker.

According to an example embodiment of the present invention, the first membrane can have a first insulation layer or a plurality of first insulation layers in addition to the first electrically conductive membrane electrode layer. Alternatively or additionally, the second membrane can have a second insulation layer or a plurality of second insulation layers in addition to the second electrically conductive membrane electrode layer. Alternatively or additionally, the central carrier layer can have a third insulation layer or a plurality of third insulation layers.

The vertical movement direction can be oriented essentially, in particular precisely, perpendicular to a main extension plane of the membranes. In this case, “essentially perpendicular” can also include smaller deviations from a perpendicular and, for example, enclose an angle of between 85 and 90 degrees between the vertical movement direction and the main extension plane of the membranes.

The inner region being arranged centrally above the through-cavity can mean that a centroid of a cross-sectional area of the through-cavity is arranged in the inner region. The centroid of the cross-sectional area of the through-cavity can be arranged exactly above a centroid of the inner region.

According to an example embodiment of the present invention, the membranes can be arranged essentially parallel with one another. In particular, an angle between the main extension planes of the membranes can be less than 5 degrees, in particular less than 2 degrees and in particular 0 degrees.

In one example embodiment of the microelectromechanical component of the present invention, the central support structure has a through-opening or a plurality of through-openings in the outer region. An area of the through-opening or of the through-openings occupies more than sixty-six, in particular more than seventy-five, preferably more than eighty, percent of the area of the outer region. Through this through-opening or the through-openings, it can be achieved that in particular little electrically conductive material of the central support structure is arranged in the outer region. The through-opening or the through-openings can thus serve to keep the outer region of the central support structure free of electrically conductive material apart from the contacting element.

In one example embodiment of the microelectromechanical component of the present invention, at least one spacer element extends through the through-opening. In particular, a plurality of spacer elements can also extend through the through-opening or through the through-openings.

In one example embodiment of the microelectromechanical component of the present invention, the central support structure has at least three fastening elements. The fastening elements connect the center electrode to the fastening region. The contacting element extends over one of the fastening elements. In particular, the fastening elements over which the contacting element does not extend can consist of an electrically insulating material.

In one example embodiment of the microelectromechanical component of the present invention, the central support structure has a tensile stress. This can make it easier to clamp the central support structure between the membranes and nevertheless to make possible a stable central support structure.

In one example embodiment of the microelectromechanical component, the tensile stress of the central support structure is at least 50 megapascals, in particular at least 80 megapascals, preferably at least 100 megapascals. The tensile stress can be at least 50 megapascals, in particular at least 80 megapascals, preferably at least 100 megapascals relative to the substrate.

In one example embodiment of the microelectromechanical component of the present invention, the tensile stress is provided by a tension layer. The tension layer can in particular consist of a non-conductive material. Alternatively or additionally, it can be provided that the tension layer is embedded in the center electrode and/or the contacting element and/or the fastening elements.

In one example embodiment of the microelectromechanical component of the present invention, an interior space between the membranes has a negative pressure, in particular a vacuum. This can in particular mean that a pressure in the interior space is less than a provided ambient pressure. In this configuration, the spacer elements are particularly advantageous since a collapse of the membrane structure due to the negative pressure in the interior space can be prevented or at least made more difficult by the spacer elements.

In one example embodiment of the microelectromechanical component of the present invention, the central support structure and the center electrode have at least one further through-opening in the inner region. At least one spacer element extends through the further through-opening. It can be provided that the central support structure and the center electrode in the inner region have more than one further through-opening with a spacer element extending through it. This can in particular reinforce the membrane structure in the inner region, in particular when a negative pressure is provided in the interior space.

The present invention also relates to a method for producing a microelectromechanical component according to the present invention. In this method, the steps explained below are carried out. First a substrate is provided. Optionally, a dielectric layer can be applied to the substrate. A first membrane layer is applied to the substrate or the dielectric layer, and the first membrane layer is structured. The first membrane layer can be at least partially or entirely electrically conductive. Furthermore, the first membrane layer can have a first insulation layer. A first sacrificial layer is subsequently applied to the first membrane layer and structured. Next, a center electrode layer is applied and the center electrode layer is structured. After this, a second sacrificial layer is applied and the second sacrificial layer is structured. Spacers are also provided. The provision of the spacers can take place together with the application of the center electrode layer or can take place independently thereof. If the provision of the spacers takes place together with the application of the center electrode layer, the spacers can be part of the center electrode layer. A second membrane layer is then applied to the second sacrificial layer and the second membrane layer is structured. The second membrane layer can be at least partially or entirely electrically conductive. Furthermore, the second membrane layer can have a second insulation layer. Following this, the first sacrificial layer and the second sacrificial layer are removed. Finally, a through-cavity is formed in the substrate.

The center electrode layer can contain a third insulation layer and, where appropriate, even a plurality of third insulation layers. This can in particular be advantageous if neither the first insulation layer of the first membrane layer nor the second insulation layer of the second membrane layer are provided, and the spacers are provided together with the center electrode layer. The third insulation layer can then prevent an electrical connection of the first membrane to the second membrane via the spacers.

In one example embodiment of the method for producing the microelectromechanical component of the present invention, the center electrode layer is applied in such a way that firstly a first center electrode layer is deposited over the entire surface. A tension layer is subsequently deposited onto the first center electrode layer and structured. After this, a second center electrode layer is deposited over the entire surface. The first center electrode layer and the second center electrode layer can together form a center electrode.

The tension layer can have a tensile stress of at least 50 megapascals, in particular at least 80 megapascals, preferably at least 100 megapascals. Furthermore, alternatively or additionally, the tension layer can be completely embedded in the first center electrode layer and the second center electrode layer.

Exemplary embodiments of the present invention are explained with reference to the figures.

### BRIEF DESCRIPTION OF THE DRAWINGS

FIG. 1 is a cross-section of a microelectromechanical component, according to an example embodiment of the present invention.

FIG. 2 is a further cross-section of the microelectromechanical component of FIG. 1.

FIG. 3 is a cross-section of a microelectromechanical component according to an example embodiment of the present invention.

FIG. 4 is a further cross-section of the microelectromechanical component of FIG. 3.

FIG. 5 is a flowchart of a production method of a microelectromechanical component according to an example embodiment of the present invention.

FIGS. 6 to 20 in each case show a cross-section and a plan view during various method steps of a production method of a microelectromechanical component, according to an example embodiment of the present invention.

### DETAILED DESCRIPTION OF EXAMPLE EMBODIMENTS

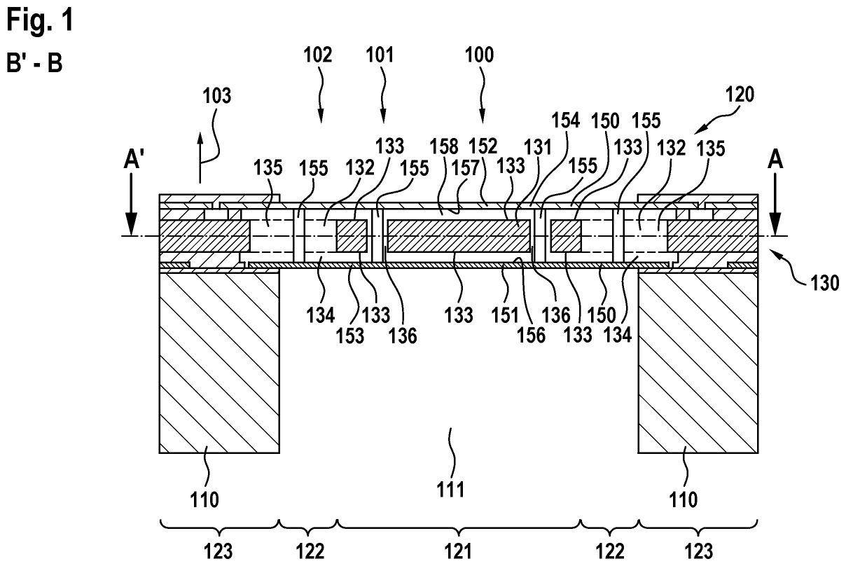

FIG. 1 shows a cross-section of a microelectromechanical component 100, which can in particular be designed as a microelectromechanical component 101 or as a microphone 102.

Alternatively, the microelectromechanical component 100 can be designed as a microelectromechanical component 101 and in particular as a loudspeaker. Furthermore, the microelectromechanical component 100 can be designed as a differential pressure sensor.

The microelectromechanical component 100 is suitable for interacting with a pressure gradient of a fluid. The microelectromechanical component 100 has a substrate 110 with a through-cavity 111 and a membrane structure 120 which at least partially spans the through-cavity 111. The membrane structure 120 has a central support structure 130 and two membranes 150. A first membrane 151 of the membrane structure 120 has a first electrically conductive membrane electrode layer 153. A second membrane 152 of the membrane structure 120 has a second electrically conductive membrane electrode layer 154. The central support structure 130 has a center electrode 131 and a contacting element 132. The first membrane 151 and the second membrane 152 are mechanically connected by means of spacer elements 155. The first membrane 151 and the second membrane 152 are deformable along a vertical movement direction 103. The membrane structure 120 has an inner region 121, an outer region 122, and a fastening region 123. The inner region 121 is arranged centrally over the through-cavity 111. The outer region 122 is arranged between the inner region 122 and the fastening region 123. The fastening region 123 is fastened to the substrate 110. The center electrode 131 is arranged entirely within the inner region 121. The contacting element 132 extends from the center electrode 131 via the outer region 122 into the fastening region 123. The contacting element 132 occupies less than thirty, preferably less than ten, percent of an area of the outer region 122.

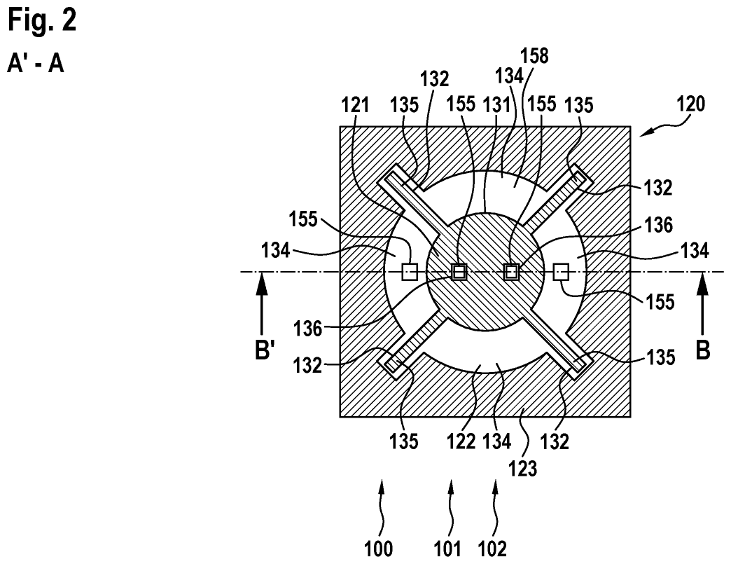

FIG. 2 shows a further cross-section of the microelectromechanical component 100 of FIG. 1 at the sectional plane denoted by AA′ in FIG. 1. FIG. 2 shows a sectional plane denoted by BB′, which corresponds to the sectional plane of FIG. 1.

In this exemplary embodiment, the center electrode 131 is represented as round, in particular circular. Alternatively, the center electrode 131 can also have other shapes, for example square, oval, rectangular or hexagonal. Furthermore, four contacting elements 132 are provided, which extend from the center electrode 131 to the fastening region 123.

In particular, the central support structure 130 can be free of electrically conductive material, apart from the contacting element 132 or the contacting elements 132, in the outer region 122. Since the central support structure 130 has only the contacting element 132 or the contacting elements 132 in the outer region 122 and can otherwise be free of electrically conductive material, the evaluation of a change in capacitance is simplified since a change in capacitance of the center electrode 131 essentially has to be evaluated with the membranes 151, 152 displaced in the inner region 121 relative to the center electrode 131, and a movement of the membranes 151, 152 in the outer region makes only a small contribution to the change in capacitance due to the contacting element 132 or the contacting elements 132. As a result, a sensitivity can be increased overall.

The microelectromechanical component 100 can in particular sense the pressure gradient of the fluid and thus be designed as a microphone 102 or pressure sensor. In these cases, a capacitance between the center electrode 131 and the membranes 151, 152 can be measured and evaluated when the pressure gradient causes the membrane structure 120 to move in the vertical movement direction 103. Furthermore, the microelectromechanical component 100 can generate the pressure gradient and then be designed as a loudspeaker. In this case, a voltage can be applied between the center electrode 131 and the membranes 151, 152 and the membrane structure 120 can thus be excited to vibrate in the vertical movement direction 103.

The inner region 121 being arranged centrally above the through-cavity 111 can mean that a centroid of a cross-sectional area of the through-cavity 111 is arranged in the inner region 121. The centroid of the cross-sectional area of the through-cavity 111 can be arranged exactly above a centroid of the inner region 121.

In FIGS. 1 and 2, the spacer elements 155 are shown arranged in a line. Of course, further spacer elements 155 can also be provided, which can also be arranged outside this line.

In FIGS. 1 and 2, optional features are also shown, which are explained below and are in each case referred to as an exemplary embodiment of the microelectromechanical component 100. These optional features are not absolutely necessary for the microelectromechanical component 100 but possibly improve the functionality. The optional features can be combined with one another.

In one exemplary embodiment of the microelectromechanical component 100, the first membrane 151 has a first insulation layer 156 or a plurality of first insulation layers 156 in addition to the first electrically conductive membrane electrode layer 153. In FIG. 1, a first insulation layer 156 is shown facing the center electrode 131. In one exemplary embodiment of the microelectromechanical component 100, the second membrane 152 has a second insulation layer 157 or a plurality of second insulation layers 157 in addition to the second electrically conductive membrane electrode layer 154. In FIG. 1, a second insulation layer 157 is shown facing the center electrode 131. In one exemplary embodiment of the microelectromechanical component 100, the central carrier layer 130 has a third insulation layer 133 or a plurality of third insulation layers 133. In FIG. 1, a third insulation layer 133 is shown facing the first membrane 151, and a further third insulation layer 133 is shown facing the second membrane 152. The insulation layers 133, 156, 157 can in particular serve to prevent an electrical short-circuit if a mechanical contact of the center electrode 131 with one of the membranes 151, 152 should result due to a movement in the vertical movement direction 103. Furthermore, the insulation layers 133, 156, 157 can serve to prevent an electrical contact of the membranes 151, 152 with one another via the spacer elements 155.

In one exemplary embodiment of the microelectromechanical component 100, the vertical movement direction 103 is oriented essentially, in particular precisely, perpendicular to a main extension plane of the membranes 151, 152. The main extension planes of the membranes 151, 152 can in particular be parallel to the sectional plane shown in FIG. 2. In this case, “essentially perpendicular” can also comprise smaller deviations from a perpendicular and, for example, include an angle of between 85 and 90 degrees between the vertical movement direction 103 and the main extension plane of the membranes 151, 152.

In one exemplary embodiment of the microelectromechanical component 100, the membranes 151, 152 are arranged essentially parallel to one another. In particular, an angle between the main extension planes of the membranes 151, 152 can be less than 5 degrees, in particular less than 2 degrees and in particular 0 degrees.

In one exemplary embodiment of the microelectromechanical component 100, the central support structure 130 has a through-opening 134 or a plurality of through-openings 134 in the outer region 122. In FIGS. 1 and 2, four through-openings 134 are in particular provided, wherein only two through-openings 134 are visible in FIG. 1 due to the choice of the sectional plane. An area of the through-opening 134 or of the through-openings 134 occupies more than seventy-five, preferably more than eighty, percent of the area of the outer region 122. Through this through-opening 134 or the through-openings 134, it can be achieved that in particular little electrically conductive material of the central support structure 130 is arranged in the outer region 122. The through-opening 134 or the through-openings 134 can thus serve to keep the outer region 122 of the central support structure 130 free of electrically conductive material apart from the contacting element 132.

In one exemplary embodiment of the microelectromechanical component 100, at least one spacer element 155 extends through the through-opening 134. In particular, a plurality of spacer elements 155 can also extend through the through-opening 134 or the through-openings 134, as shown in FIGS. 1 and 2.

In one exemplary embodiment of the microelectromechanical component 100, the central support structure 130 has at least three fastening elements 135. FIG. 2 in particular shows four fastening elements 135. The fastening elements 135 connect the center electrode 131 to the fastening region 123. The contacting element 132 extends over one of the fastening regions 135, wherein a respective contacting element 132 extends over each of the fastening elements 135 in the exemplary embodiment of FIGS. 1 and 2. However, this is not absolutely necessary; individual or a plurality of the fastening elements 135 can also be designed without contacting element 132. In particular, the fastening elements 135 over which the contacting element 132 does not extend can consist of an electrically insulating material. At least three fastening regions 135 may be necessary so that the center electrode 131 does not tilt, in particular when the fastening elements 135 are to have small dimensions. A number of fastening elements 135 can be adapted, for example, to a shape of the center electrode 131. A round or a hexagonal center electrode 131 can, for example, be fastened with three fastening elements 135; a square or rectangular or oval or round center electrode 131 can, for example, be fastened with four fastening elements 135.

In one exemplary embodiment of the microelectromechanical component 100, an interior space 158 between the membranes 151, 152 has a negative pressure, in particular a vacuum. This can in particular mean that a pressure in the interior space 158 is less than a provided ambient pressure. In this configuration, the spacer elements 155 are particularly advantageous since a collapse of the membrane structure 120 due to the negative pressure in the interior space 158 can be prevented or at least made more difficult by the spacer elements 155. In this case, the contact points of the spacer elements 155 on the first membrane 151 can be in particular parallel to the contact points of the spacer elements 155 on the second membrane 152.

In one exemplary embodiment of the microelectromechanical component 100, the central support structure 130 and the center electrode 131 have at least one further through-opening 136 in the inner region 121. At least one spacer element 155 extends through the further through-opening 136. The central support structure 130 and the center electrode 131 in the inner region 121 can have more than one further through-opening 136 with a spacer element 155 extending through it. This can in particular reinforce the membrane structure 120 in the inner region 121, in particular when a negative pressure is provided in the interior space 158. FIGS. 1 and 2 each show two further through-openings 136 with spacer elements 155 extending through them, wherein even more through-openings 136 with spacer elements 155 extending through them can be provided, where appropriate.

The first electrically conductive membrane electrode layer 153 and/or the second electrically conductive membrane electrode layer 154 and/or the center electrode and/or the contacting element 132 or the contacting elements 132 can have doped polysilicon or consist of doped polysilicon. Alternatively or additionally, the first insulation layer 156 and/or the second insulation layer 157 and/or the third insulation layer 133 can comprise an undoped silicon, in particular polysilicon, or consist of an undoped silicon, in particular polysilicon, or can comprise a silicon nitride or consist of a silicon nitride.

A thickness of the first membrane 151 or of the first electrically conductive membrane electrode layer 153 in relation to the vertical movement direction 103 can be at least 150 nanometers and at most 3 micrometers. Alternatively or additionally, a thickness of the second membrane 152 or of the second electrically conductive membrane electrode layer 154 in relation to the vertical movement direction 103 can be at least 150 nanometers and at most 3 micrometers. Alternatively or additionally, a distance of the first membrane 151 or of the first electrically conductive membrane electrode layer 153 from the center electrode 131 in relation to the vertical movement direction 103 can be at least 300 nanometers and at most 5 micrometers. Alternatively or additionally, a distance of the second membrane 152 or of the second electrically conductive membrane electrode layer 154 from the center electrode 131 in relation to the vertical movement direction 103 can be at least 300 nanometers and at most 5 micrometers. Alternatively or additionally, a thickness of the center electrode 131 in relation to the vertical movement direction 103 can be at least 300 nanometers and at most 30 micrometers.

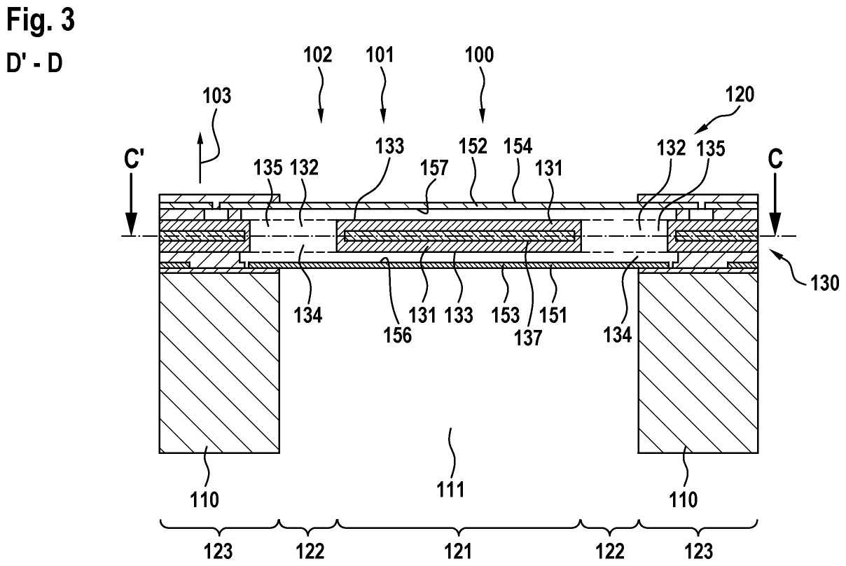

FIG. 3 shows a cross-section of a further microelectromechanical component 100, which corresponds to the microelectromechanical component 100 of FIGS. 1 and 2, except where differences are described below. In the representation of FIG. 3, the spacer elements 155 and the optional further through-openings 136 are omitted in order to increase the clarity. Of course, spacer elements 155 and optional further through-openings 136 can also be provided in the exemplary embodiment of FIG. 3. In the exemplary embodiment of the microelectromechanical component 100 of FIG. 3, the central support structure 130 has a tensile stress. This can make it simpler to clamp the central support structure 130 between the membranes 151, 152 and nevertheless to make possible a stable central support structure 120.

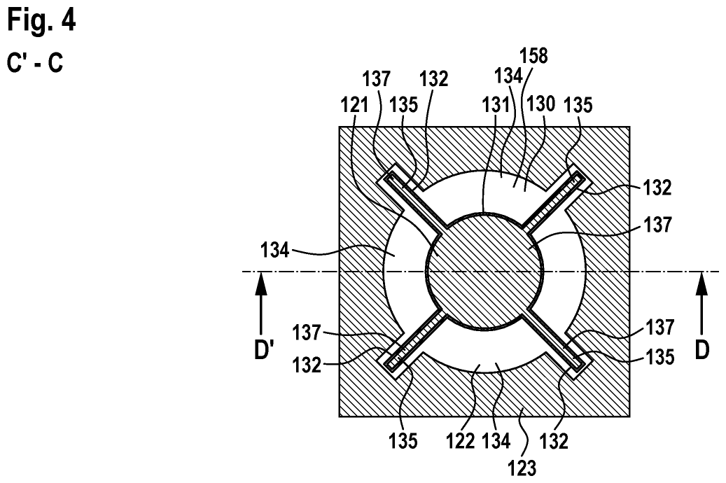

FIG. 4 shows a further cross-section of the microelectromechanical component 100 of FIG. 3 at the sectional plane denoted by CC′ in FIG. 1. FIG. 4 shows a sectional plane denoted by DD′, which corresponds to the sectional plane of FIG. 3. In FIGS. 3 and 4, optional features are also shown, which are explained below and are in each case referred to as an exemplary embodiment of the microelectromechanical component 100. These optional features are not absolutely necessary for the microelectromechanical component 100 but possibly improve the functionality. The optional features can be combined with one another. The optional features of FIGS. 3 and 4 can also be provided in the exemplary embodiments which have been explained in connection with FIGS. 1 and 2.

In one exemplary embodiment of the microelectromechanical component 100, the tensile stress is at least 50 megapascals, in particular at least 80 megapascals, preferably at least 100 megapascals. The tensile stress can be at least 50 megapascals, in particular at least 80 megapascals, preferably at least 100 megapascals relative to the substrate 110.

In one exemplary embodiment of the microelectromechanical component 100, the tensile stress is provided by a tension layer 137. The tension layer 137 can in particular consist of a non-conductive material. Alternatively or additionally, the tension layer 137 can be embedded in the center electrode 131 and/or the contacting element 132 and/or the fastening elements 135. This configuration is shown in FIGS. 3 and 4, wherein the tension layer 137 is embedded in all contacting elements 132. In particular, the center electrode 131 and the contacting element 132 or the center electrode 131 and the contacting elements 132 can thus completely surround the tension layer 137 so that the center electrode 131 and the contacting element 132 or the center electrode 131 and the contacting elements 132 separate the tension layer 137 from the interior space 158. If further recesses 136 are provided in the center electrode 131, it can likewise be provided at these locations that the center electrode 131 separates the tension layer 137 from the further recesses 136.

The tension layer 137 can in particular comprise a silicon nitride or consist of silicon nitride. A thickness of the tension layer 137 in relation to the vertical movement direction 103 can be one micrometer at most.

In the exemplary embodiments of FIGS. 1 to 4, a radius of the center electrode 131 can be at least four times an annular width of a circular ring of the outer region 122.

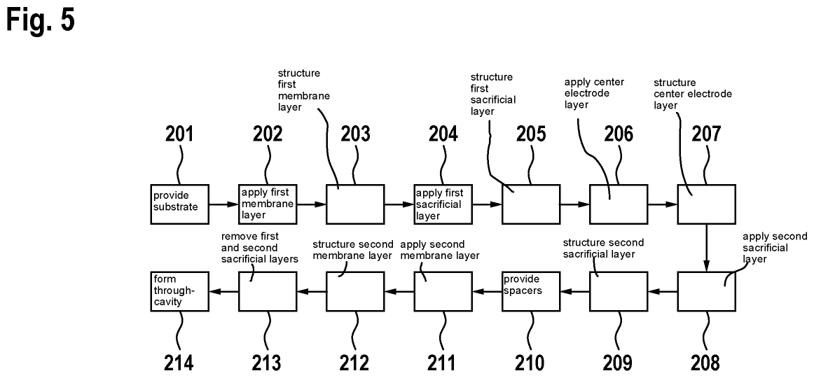

FIG. 5 shows a flowchart 200 of a method for producing a microelectromechanical component 100, which can be designed, for example, as shown in FIGS. 1 to 4. In a first method step 201, a substrate 110 is provided. In a second method step 202, a first membrane layer, which can later contain the first membrane 151, is applied to the substrate 110, and the first membrane layer is structured in a third method step 203. The first membrane layer can be at least partially or entirely electrically conductive and in particular contain the first electrically conductive membrane electrode layer 153. Furthermore, the first membrane layer can have the first insulation layer 156. A first sacrificial layer is subsequently applied to the first membrane layer in a fourth method step 204 and is structured in a fifth method step 205. Next, a center electrode layer is applied in a sixth method step 206, and the center electrode layer is structured in a seventh method step 207. After this, a second sacrificial layer is applied in an eighth method step 208 and the second sacrificial layer is structured in a ninth method step 209. Furthermore, spacers are provided in a tenth method step 210. The provision of the spacers can take place together with the application of the center electrode layer or can take place independently thereof. If the provision of the spacers takes place together with the application of the center electrode layer, the spacers can be part of the center electrode layer. In an eleventh method step 211, a second membrane layer, which can later contain the second membrane 152, is applied to the second sacrificial layer, and the second membrane layer is structured in a twelfth method step 212. The second membrane layer can be at least partially or entirely electrically conductive and in particular contain the second electrically conductive membrane electrode layer 154. Furthermore, the second membrane layer can have the second insulation layer 157. Next, the first sacrificial layer and the second sacrificial layer are removed in a thirteenth method step 213. Finally, a through-cavity 111 is formed in the substrate 110 in a fourteenth method step 214.

The center electrode layer can contain the third insulation layer 133 and, where appropriate, even a plurality of third insulation layers 133. This can in particular be advantageous if neither the first insulation layer 156 of the first membrane layer nor the second insulation layer 157 of the second membrane layer are provided, and the spacers 155 are provided together with the center electrode layer. The third insulation layer 133 can then prevent an electrical connection of the first membrane 151 to the second membrane 152 via the spacers 155.

In one embodiment of the method for producing the microelectromechanical component 100, the center electrode layer is applied in such a way that first a first center electrode layer is deposited over the entire surface. The tension layer 137 is subsequently deposited onto the first center electrode layer and structured. After this, a second center electrode layer is deposited over the entire surface. The first center electrode layer and the second center electrode layer can together form a center electrode 131.

The tension layer 137 can have a tensile stress of at least 50 megapascals, in particular at least 80 megapascals, preferably at least 100 megapascals. Furthermore, alternatively or additionally, the tension layer 137 can be completely embedded in the first center electrode layer and the second center electrode layer. The tensile stress can be at least 50 megapascals, in particular at least 80 megapascals, preferably at least 100 megapascals relative to the substrate 111.

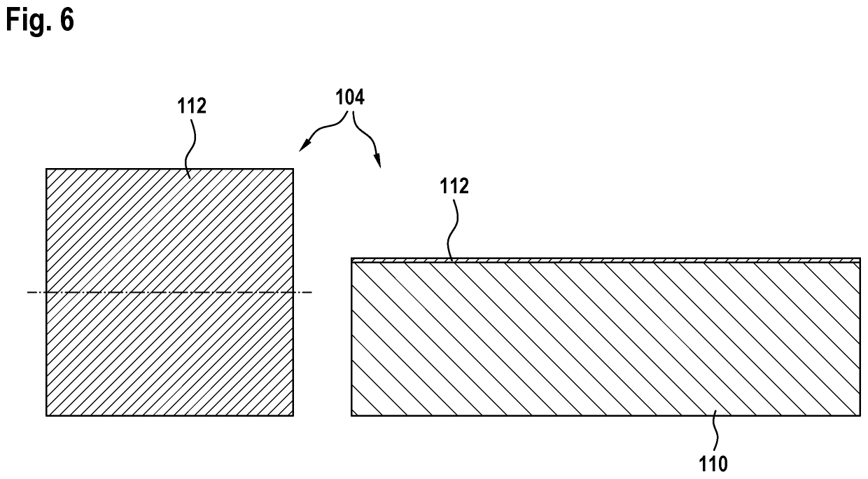

FIG. 6 shows in a left-hand region a plan view and in a right-hand region a cross-section of an intermediate product 104 during a method for producing a microelectromechanical component 100. The first method step 201 has already been carried out, and the substrate 110 has already been provided. Furthermore, a dielectric layer 112 has optionally been applied to the substrate 111. The dielectric layer 112 can serve as an electrical insulation layer between the substrate 110 and the first membrane 151 and can furthermore also serve as an etch stop layer in the case of a back-side etching by means of which the through-cavity 111 can be produced.

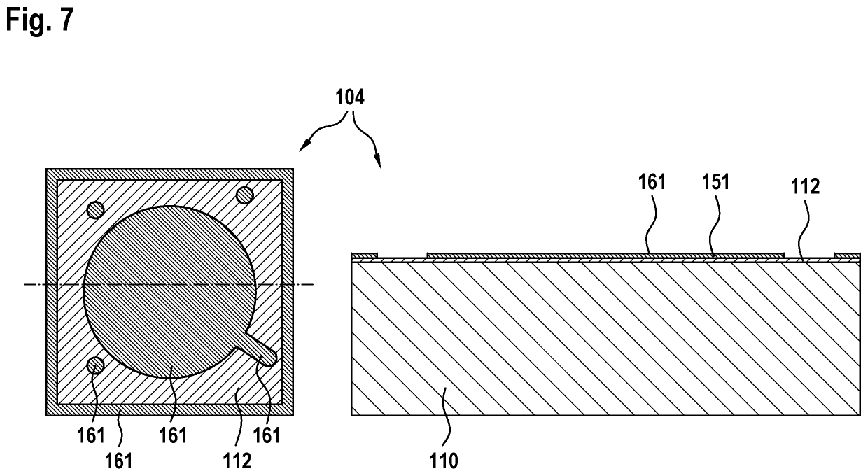

FIG. 7 shows in a left-hand region a plan view and in a right-hand region a cross-section of a further intermediate product 104 during a method for producing a microelectromechanical component 100. The second method step 202 and the third method step 203 have already been carried out. A first membrane layer 161, which is already structured and which can form the first membrane 151 in the finished microelectromechanical component 100, is now arranged on the dielectric layer 112. The first membrane layer 161 is preferably electrically conductive or electrically conductive in partial regions. A doped polysilicon is preferably used for the first membrane layer 161. The first membrane layer 161 is preferably designed to have a thickness of at least 150 nanometers to at most 3 micrometers.

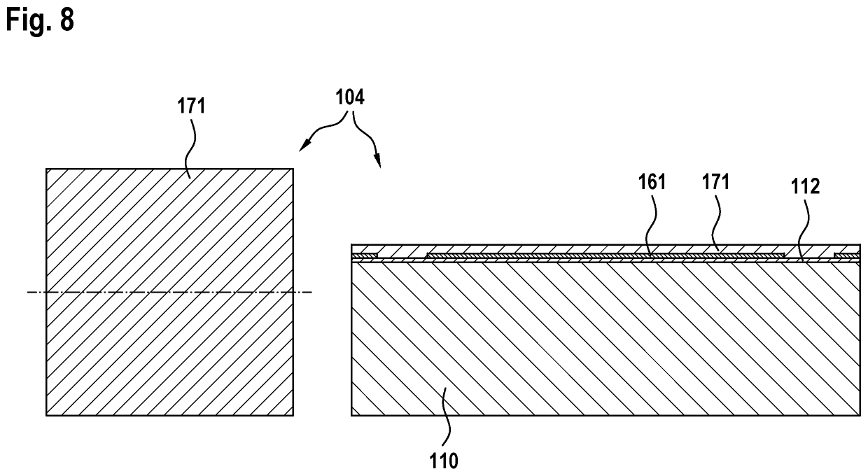

FIG. 8 shows in a left-hand region a plan view and in a right-hand region a cross-section of a further intermediate product 104 during a method for producing a microelectromechanical component 100. The fourth method step 204 and the fifth method step 205 have already been carried out. A first sacrificial layer 171, which is already structured, is now arranged on the first membrane layer 161. The first sacrificial layer 171 is preferably a silicon oxide layer. The first sacrificial layer 171 preferably has a thickness of at least 300 nanometers, at most 5 micrometers.

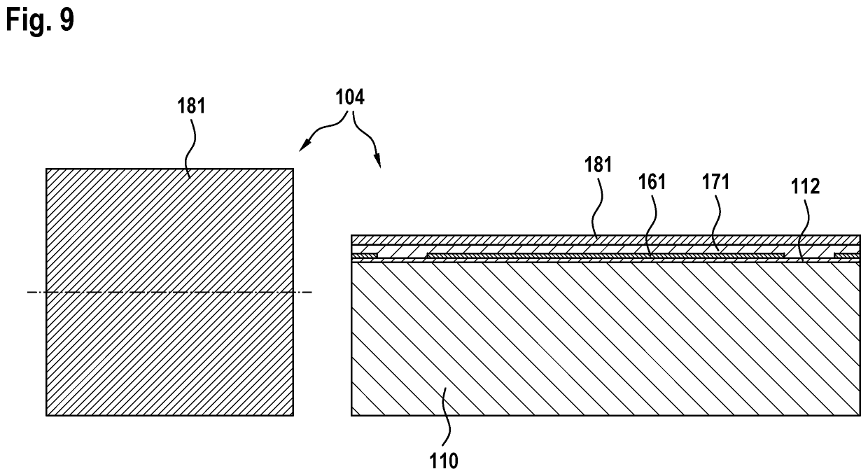

FIG. 9 shows in a left-hand region a plan view and in a right-hand region a cross-section of a further intermediate product 104 during a method for producing a microelectromechanical component 100. The sixth method step 206 has partially been carried out. A first center electrode layer 181 has been applied to the first sacrificial layer 171. The first center electrode layer 181 can in particular be a doped polysilicon layer.

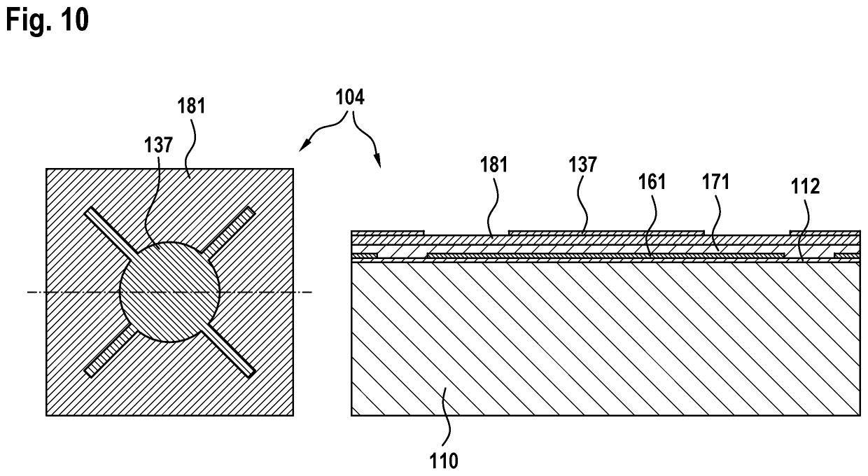

FIG. 10 shows in a left-hand region a plan view and in a right-hand region a cross-section of a further intermediate product 104 during a method for producing a microelectromechanical component 100. An optional intermediate step of the sixth method step 206 has been carried out. A tension layer 137 having the properties already described above has been applied to the first center electrode layer 181. In particular, the tension layer 137 has also been structured.

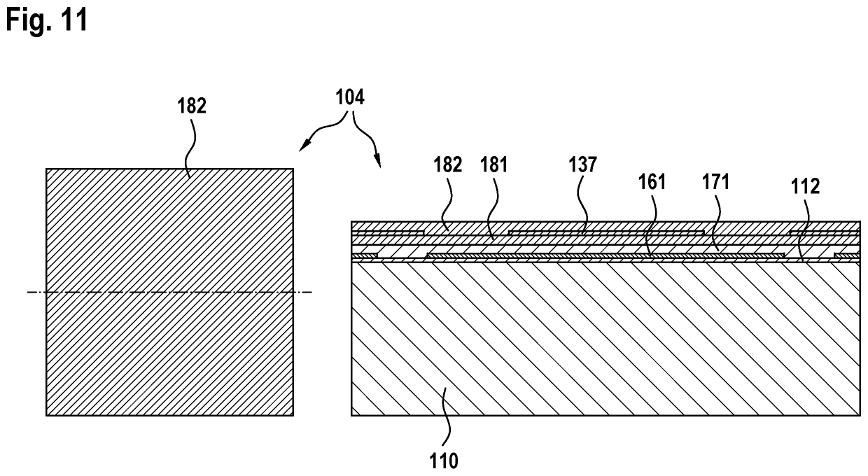

FIG. 11 shows in a left-hand region a plan view and in a right-hand region a cross-section of a further intermediate product 104 during a method for producing a microelectromechanical component 100. The sixth method step 206 has now been carried out completely. A second center electrode layer 182 has been applied to the first center electrode layer 181 or the tension layer 137. The second center electrode layer 182 can in particular be a doped polysilicon layer. The tension layer 137 is completely embedded in the center electrode layers 181, 182.

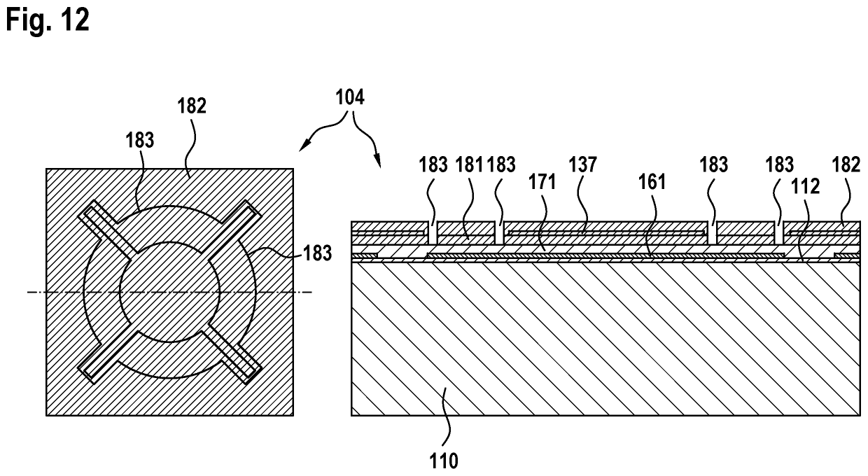

FIG. 12 shows in a left-hand region a plan view and in a right-hand region a cross-section of a further intermediate product 104 during a method for producing a microelectromechanical component 100. The seventh method step 207 has been prepared at least partially. Trenches 183 have been introduced into the center electrode layers 181, 182 using a trenching method. A width of the trenches 183 can preferably be less than a layer thickness of the center electrode layers 181, 182 with the embedded tension layer 137.

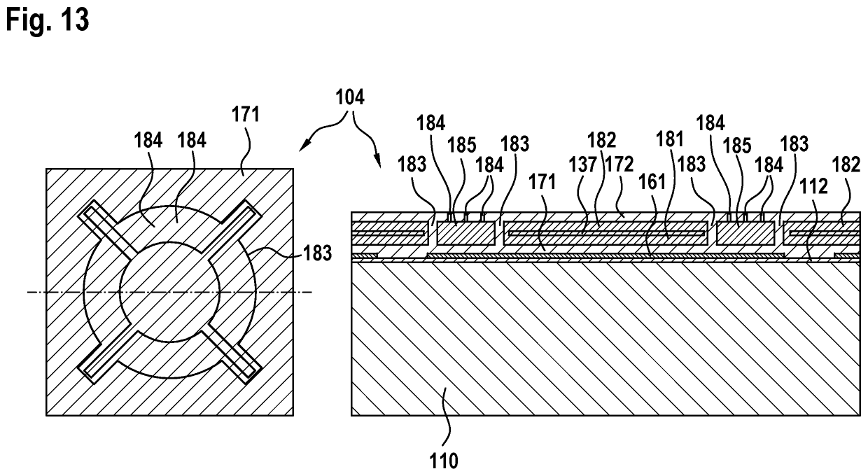

FIG. 13 shows in a left-hand region a plan view and in a right-hand region a cross-section of a further intermediate product 104 during a method for producing a microelectromechanical component 100. The seventh method step 207 has been prepared at least partially, and the eighth method step 208 and the ninth method step 209 have been carried out at least partially. A second sacrificial layer 172 has been applied to the second center electrode layer 182 and also fills the trenches 183. A thickness of the second sacrificial layer 172 can be more than twice a width of the trenches 183. The second sacrificial layer 172 is preferably a silicon oxide layer. Furthermore, narrow accesses 184 have been etched into the second sacrificial layer 172. The narrow accesses 184 extend into regions 185 of the center electrode layers 181, 182, which are surrounded by trenches 184 and which are provided for the through-openings 134 of the central support layer 130.

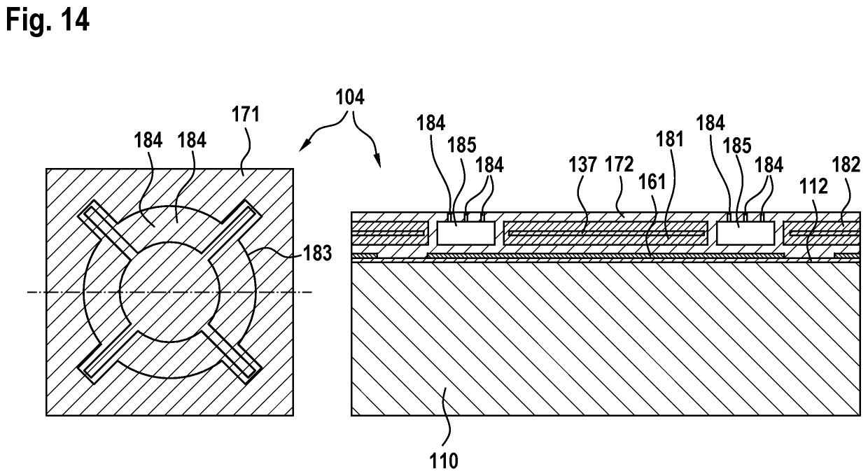

FIG. 14 shows in a left-hand region a plan view and in a right-hand region a cross-section of a further intermediate product 104 during a method for producing a microelectromechanical component 100. The seventh method step 207 has been carried out by removing material of the center electrode layers 181, 182 from the regions 185 through the narrow accesses 184 by means of an isotropic etching method.

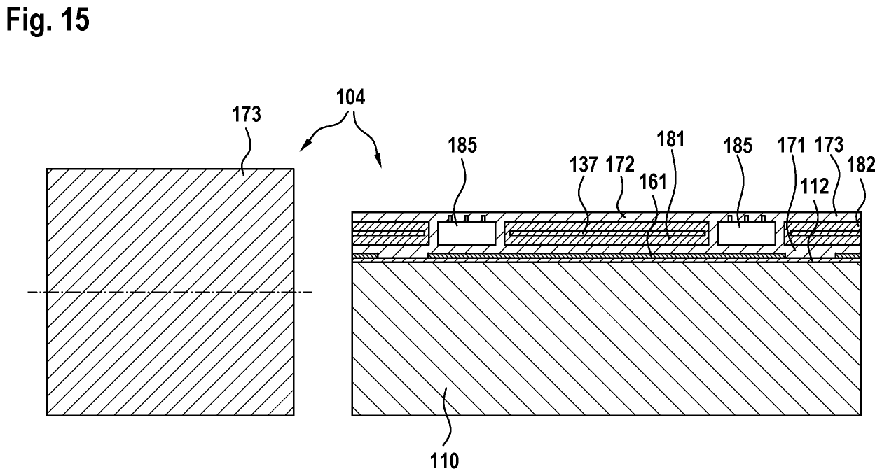

FIG. 15 shows in a left-hand region a plan view and in a right-hand region a cross-section of a further intermediate product 104 during a method for producing a microelectromechanical component 100. The eighth method step 208 and the ninth method step 209 have been carried out. A further second sacrificial layer 173 has been applied to the second sacrificial layer 172. An overall layer consisting of the second sacrificial layer 172 and the further second sacrificial layer 173 can likewise be referred to as the second sacrificial layer. The further second sacrificial layer 173 is preferably a silicon oxide layer. The second sacrificial layer 172 and the further second sacrificial layer 173 together preferably have a thickness of at least 300 nanometers, at most 5 micrometers.

The tenth method step 210 can now be performed, and the spacer elements 155 can now be provided. Alternatively, the tenth method step 210 can be performed within the scope of the sixth method step 206 and of the seventh method step 207.

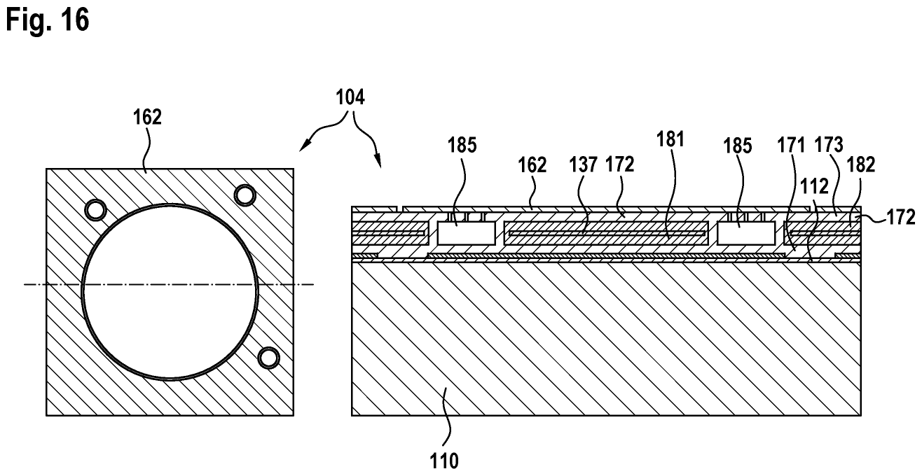

FIG. 16 shows in a left-hand region a plan view and in a right-hand region a cross-section of a further intermediate product 104 during a method for producing a microelectromechanical component 100. The eleventh method step 211 and the twelfth method step 212 have been carried out. A second membrane layer 162 has been applied to the further second sacrificial layer 173 and structured. The second membrane layer 162 can form the second membrane 152 in the finished microelectromechanical component 100. The second membrane layer 162 is preferably electrically conductive or electrically conductive in partial regions. A doped polysilicon is preferably used for the second membrane layer 162. The second membrane layer 162 is preferably designed to have a thickness of at least 150 nanometers to at most 3 micrometers.

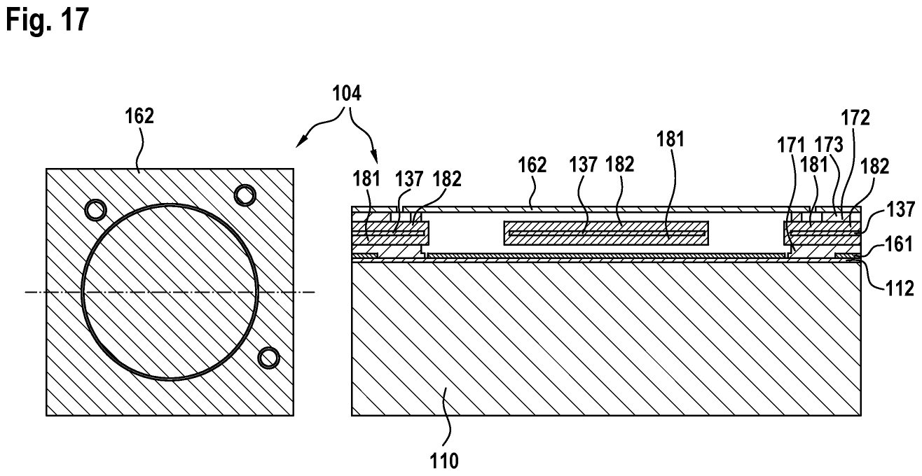

FIG. 17 shows in a left-hand region a plan view and in a right-hand region a cross-section of a further intermediate product 104 during a method for producing a microelectromechanical component 100. The thirteenth method step 213 has been carried out and the sacrificial layers 171, 172, 173 have been removed, for example by means of an isotropic etching method.

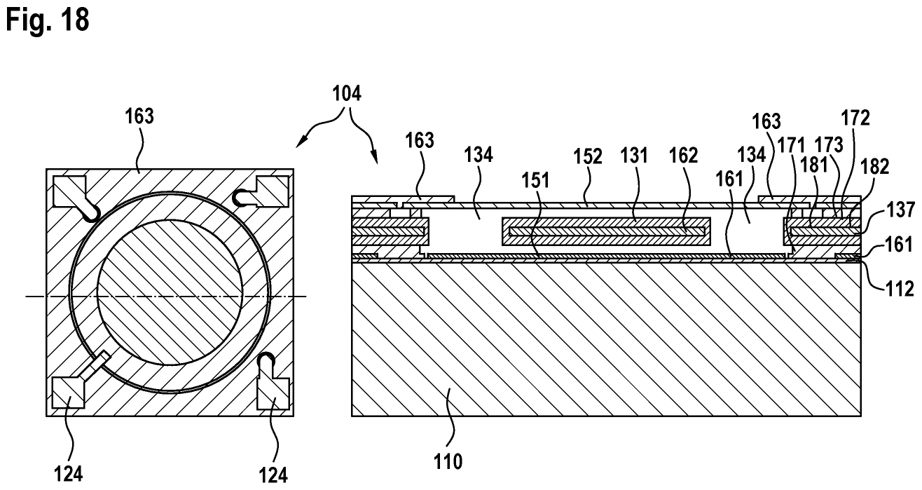

FIG. 18 shows in a left-hand region a plan view and in a right-hand region a cross-section of a further intermediate product 104 during a method for producing a microelectromechanical component 100. An optional method step has been carried out, in which a negative pressure is enclosed between the two membrane layers 161, 162 via a sealing method, for example a layer deposition or a laser resealing method. A sealing layer 163 has been applied here, which can be removed again in regions without etching access, in particular in the region of the second membrane 152. Optionally, electrical contact regions 124 can also be created. These electrical contact regions can also be provided in the microelectromechanical components of FIGS. 1 to 4 and serve for reading a capacitance signal or for applying a voltage.

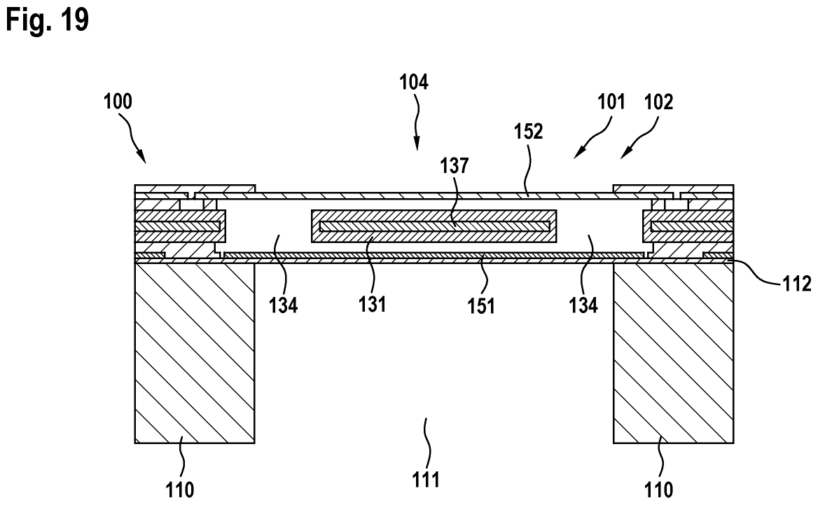

FIG. 19 shows a cross-section of a further intermediate product 104 during a method for producing a microelectromechanical component 100. The fourteenth method step 214 has been carried out, and the through-cavity 111 has been created in the substrate 110. The intermediate product 104 now substantially corresponds to the microelectromechanical component 100 or the microelectromechanical acoustic component 101 or the microphone 102 of FIGS. 3 and 4.

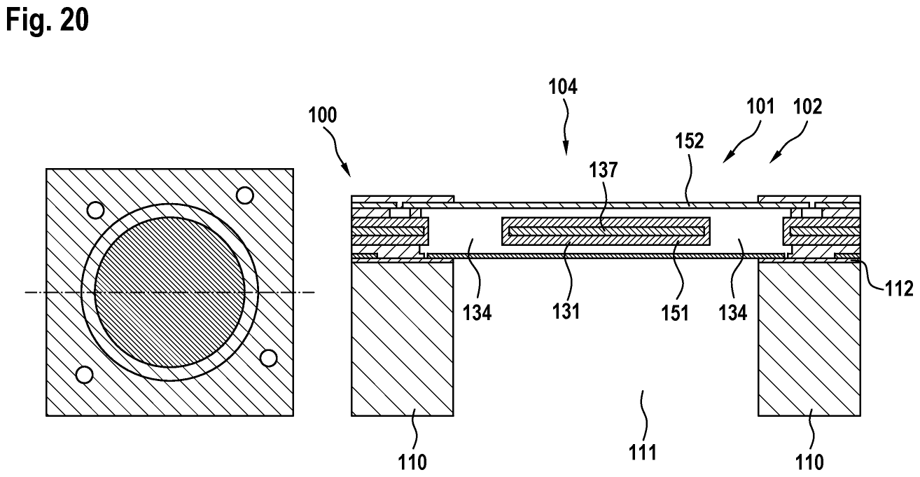

FIG. 20 shows a cross-section of a further intermediate product 104 during a method for producing a microelectromechanical component 100. After a further optional method step, the dielectric layer 112 has also been removed in the region of the through-cavity 111. The microelectromechanical component 100 or microelectromechanical acoustic component 101 or microphone 102 shown in FIGS. 3 and 4 is now finished.

Although the present invention has been described in detail by the preferred exemplary embodiments, the present invention is not limited to the disclosed examples and other variations may be derived therefrom by a person skilled in the art without departing from the scope of protection of the present invention.

What is claimed is:

1. A microelectromechanical component for interacting with a pressure gradient of a fluid, comprising:
a substrate with a through-cavity;
a membrane structure which at least partially spans the through-cavity, wherein the membrane structure has a central support structure and two membranes, wherein a first membrane of the membrane structure has a first electrically conductive membrane electrode layer, and a second membrane of the membrane structure has a second electrically conductive membrane electrode layer, wherein the central support structure has at least one center electrode and a contacting element, wherein the first membrane and the second membrane are mechanically connected by spacer elements, wherein the first membrane and the second membrane are able to deform along a vertical movement direction, wherein the membrane structure has an inner region, an outer region, and a fastening region, wherein the inner region is arranged centrally above the through-cavity, wherein the outer region is arranged between the inner region and the fastening region, wherein the fastening region is fastened to the substrate, wherein the center electrode is arranged entirely within the inner region, wherein the contacting element extends from the center electrode via the outer region into the fastening region, and wherein the contacting element occupies less than thirty percent of an area of the outer region.

2. The microelectromechanical device according to claim 1, wherein the central support structure has a through-opening or a plurality of through-openings in the outer region, wherein an area of the through-opening or of the through-openings of the central support structure occupies more than sixty-six percent of the area of the outer region.

3. The microelectromechanical component according to claim 2, wherein at least one spacer element extends through the through-opening.

4. The microelectromechanical device according to claim 1, wherein the central support structure has a tensile stress.

5. The microelectromechanical component according to claim 4, wherein the tensile stress is at least 50 megapascals.

6. The microelectromechanical device according to claim 4, wherein the tensile stress is provided by a tension layer.

7. The microelectromechanical device according to claim 1, wherein an interior space between the membranes has a negative pressure.

8. The microelectromechanical device according to claim 1, wherein the central support structure and the center electrode have at least one further through-opening in the inner region, and wherein at least one spacer element extends through the further through-opening.

9. A method for producing a microelectromechanical component A microelectromechanical component for interacting with a pressure gradient of a fluid, including:
a substrate with a through-cavity; and
a membrane structure which at least partially spans the through-cavity, wherein the membrane structure has a central support structure and two membranes, wherein a first membrane of the membrane structure has a first electrically conductive membrane electrode layer, and a second membrane of the membrane structure has a second electrically conductive membrane electrode layer, wherein the central support structure has at least one center electrode and a contacting element, wherein the first membrane and the second membrane are mechanically connected by spacer elements, wherein the first membrane and the second membrane are able to deform along a vertical movement direction, wherein the membrane structure has an inner region, an outer region, and a fastening region, wherein the inner region is arranged centrally above the through-cavity, wherein the outer region is arranged between the inner region and the fastening region, wherein the fastening region is fastened to the substrate, wherein the center electrode is arranged entirely within the inner region, wherein the contacting element extends from the center electrode via the outer region into the fastening region, and wherein the contacting element occupies less than thirty percent of an area of the outer region, the method comprising the following steps:
providing the substrate;
applying a first membrane layer;
structuring the first membrane layer;
applying a first sacrificial layer;
structuring the first sacrificial layer;
applying a center electrode layer;
structuring the center electrode layer;
applying a second sacrificial layer;
structuring the second sacrificial layer;
providing the spacers;
applying a second membrane layer;
structuring the second membrane layer;
removing the sacrificial layers; and
forming the through-cavity in the substrate.

10. The method according to claim 9, wherein the center electrode layer is applied in such a way that a first center electrode layer is deposited over an entire surface, a tension layer with a tensile stress of at least 50 megapascals is subsequently deposited onto the first center electrode layer and structured, and subsequently a second center electrode layer is deposited over the entire surface.
